(19) United States
(12) Patent Application Publication
(10) Pub. No.: US 2026/0157004 A1
(43) Pub. Date: Jun. 4, 2026

(54) DISPLAY DEVICE

(71) Applicant: AUO Corporation, Hsinchu City (TW)

(72) Inventor: Fang-Cheng Yu, Hsinchu City (TW)

(73) Assignee: AUO Corporation, Hsinchu City (TW)

(21) Appl. No.: 19/226,177

(22) Filed: Jun. 3, 2025

(30) Foreign Application Priority Data
Dec. 3, 2024 (TW) 113146702

(51) Int. Cl. H10H 29/851; H10H 29/80

(52) U.S. Cl. CPC H10H 29/8514; H10H 29/882

(57) ABSTRACT

A display device includes a pixel unit including a first region and a second region, the first region includes a first sub-pixel and a blocking layer. The first sub-pixel includes a first light-emitting element that emits light of a first color, and a first color conversion structure. The first color conversion structure covers the first light-emitting element and converts the light of the first color into light of a second color, the blocking layer surrounds the first light-emitting element, the second region includes a second sub-pixel, a third sub-pixel and a scattering particle layer located between the second light-emitting element and the third light-emitting element, and on at least one side of the second and third light-emitting elements. The second sub-pixel includes a second light-emitting element which emits light of a third color. The third sub-pixel includes a third light-emitting element which emits light of a first color.

### CROSS-REFERENCE TO RELATED APPLICATION

This application claims the priority benefit of Taiwan application serial no. 113146702, filed on Dec. 3, 2024. The entirety of the above-mentioned patent application is hereby incorporated by reference herein and made a part of this specification.

### BACKGROUND

### Technical Field

The disclosure relates to a display device.

### Description of Related Art

The color conversion architecture of micro light-emitting diode (μLED) includes a wall bank structure, a color conversion layer, and an optically clear adhesive (OCA). The wall bank structure, possessing a high optical density value, effectively suppresses the cross talk phenomenon of color conversion light. As resolution increases, the wall bank material encounters difficulties in simultaneously maintaining a high optical density value and a high aspect ratio. Although removing wall bank structures from sub-pixels of the non-color conversion layers may reduce pixel dimensions to meet resolution requirements, the point light source characteristics of μLEDs are consequently affected by the distance between wall banks and their high optical density properties, resulting in significant variations in picture quality. Effective arrangement of wall bank structures, color conversion layers, and optical packaging layers within the color conversion architecture of μLEDs constitutes a matter of significant importance with respect to the the picture quality of μLEDs.

### SUMMARY

A display device is provided in the present disclosure. The display device includes a pixel unit. The pixel unit includes a first region and a second region. The first region includes a first sub-pixel and a blocking layer. The first sub-pixel includes a first light-emitting element and a first color conversion structure. The first light-emitting element emits light of a first color. The first color conversion structure located on the first light-emitting element covers the first light-emitting element and converts the first color into a second color. The blocking layer surrounds the first light-emitting element. The second region includes a second sub-pixel, a third sub-pixel and a scattering particle layer. The second sub-pixel includes a second light-emitting element, and the second light-emitting element emits light of a third color. The third sub-pixel includes a third light-emitting element, and the third light-emitting element emits light of the first color. The scattering particle layer is located between the second light-emitting element and the third light-emitting element, on at least one side of the second light-emitting element, and on at least one side of the third light-emitting element.

Based on the above, the first color conversion structure covers the first light-emitting element, the blocking layer surrounds the first light-emitting element, and the scattering particle layer is located between the second light-emitting element and the third light-emitting element, at least one side of the second light-emitting element, and at least one side of the third light-emitting element. In this way, the display device may effectively suppress the cross talk phenomenon of color conversion light, and the display device may have better picture quality.

### BRIEF DESCRIPTION OF THE DRAWINGS

FIG. 1A is a top schematic view of a pixel unit according to an embodiment of the disclosure.

FIG. 1B is a cross-sectional schematic diagram of FIG. 1A along the section line I-I′.

FIG. 1C is a diagram showing the relationship between the viewing angle and the brightness of the second sub-pixel according to an embodiment of the disclosure.

FIG. 1D is a diagram showing the relationship between the viewing angle and the brightness of the third sub-pixel according to an embodiment of the disclosure.

FIG. 2A is a top schematic view of a pixel unit according to an embodiment of the disclosure.

FIG. 2B is a cross-sectional schematic diagram of FIG. 2A along the section line I-I′.

FIG. 3A is a top schematic view of a pixel unit according to an embodiment of the disclosure.

FIG. 3B is a cross-sectional schematic diagram of FIG. 3A along the section line A-A′ and the section line B-B′.

### DETAILED DESCRIPTION OF DISCLOSED EMBODIMENTS

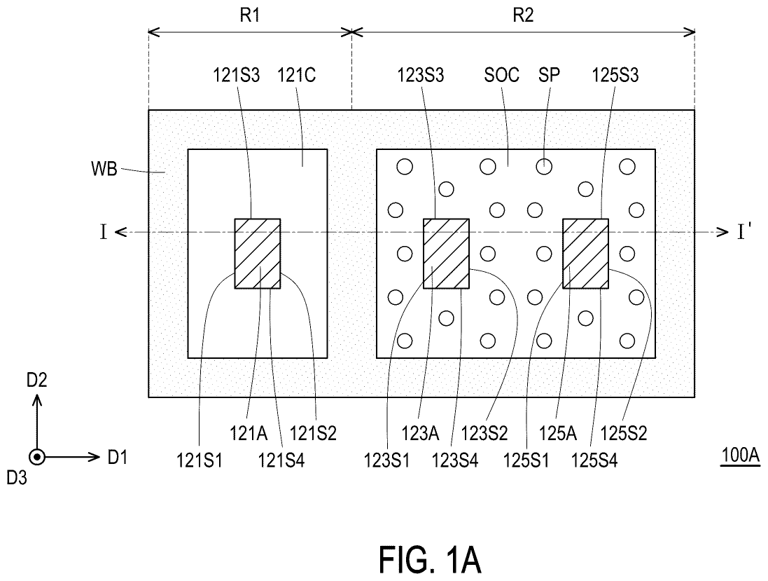

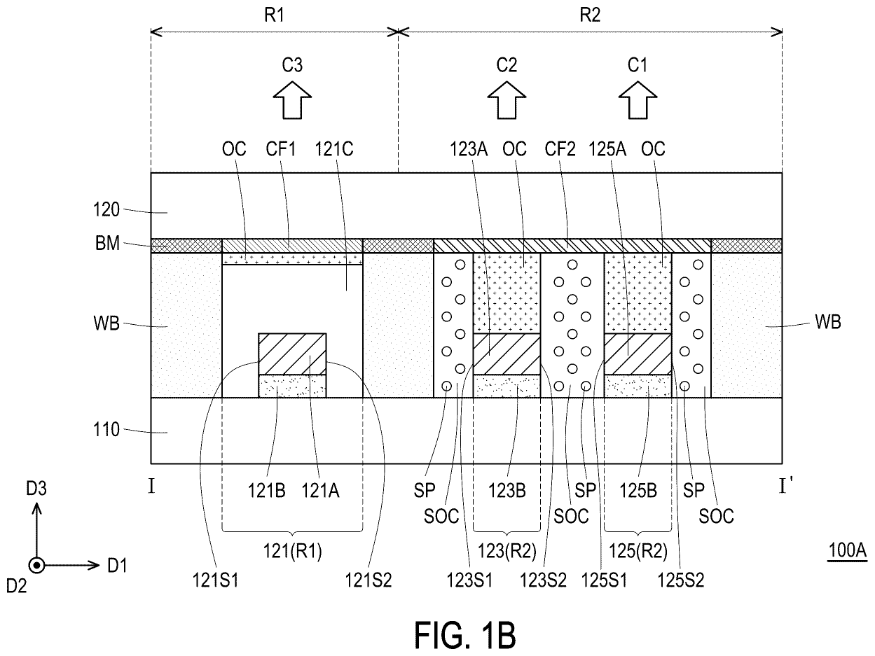

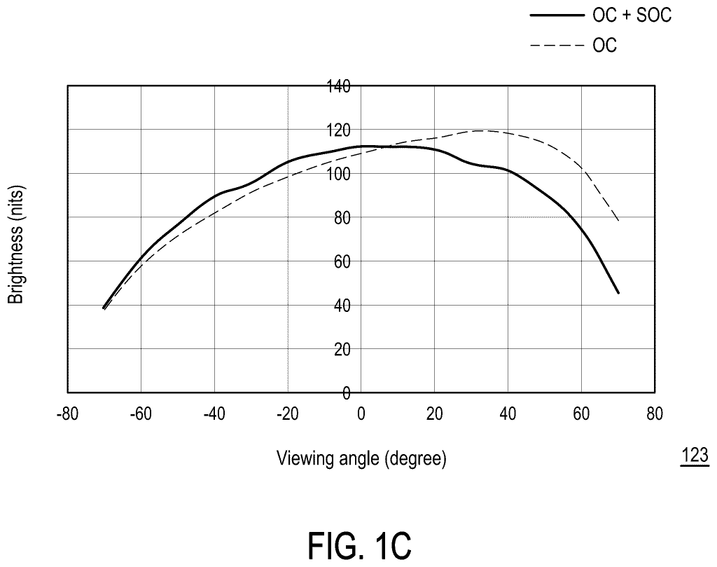

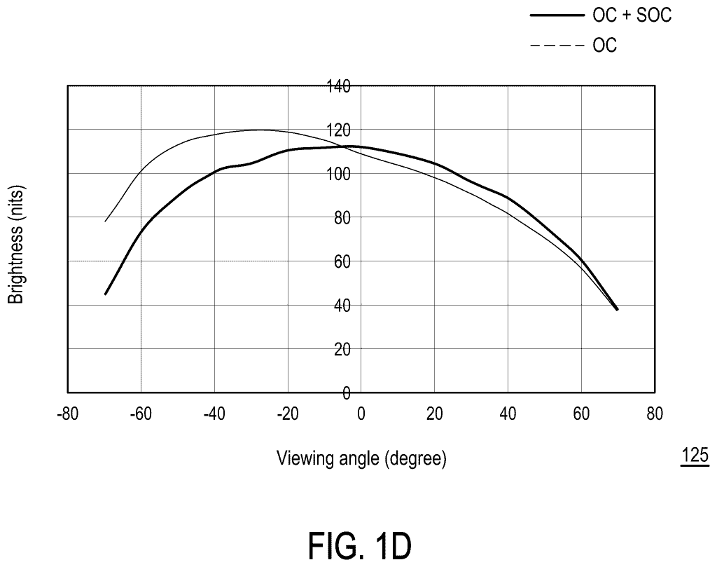

1 FIG. 1A is a top schematic view of a pixel unit according to an embodiment of the disclosure. FIG. 1B is a cross-sectional schematic diagram of FIG. 1A along the section line I-I′. Please refer to FIG. 1A and FIG. 1B simultaneously. A display device includes a pixel unit 100A, the pixel unit 100A includes a first region R1 and a second region R2. The first region includes a first sub-pixel 121 and a blocking layer WB, the first sub-pixel 121 includes a first light-emitting element 121A and a first color conversion structure 121C. The first light-emitting element 121A emits light of a first color C1. The first color conversion structure 121C is disposed on the first light-emitting element 121A to cover the first light-emitting element 121A and is adapted to convert the light of the first color C1 emitted by the first light-emitting element 121A into light of a second color C2, and the blocking layer WB surrounds the first light-emitting element 121A.

The second region R2 includes a second sub-pixel 123, a third sub-pixel 125, a blocking layer WB and a scattering particle layer SOC. The second sub-pixel 123 includes a second light-emitting element 123A, which emits light of a third color C3. The third sub-pixel 125 includes a third light-emitting element 125A, which emits light of the first color C1. The scattering particle layer SOC is located between the second light-emitting element 123A and the third light-emitting element 125A, on at least one side of the second light-emitting element 123A, and on at least one side of the third light-emitting element 125A.

As shown in FIG. 1B, the display device also includes a first substrate 110 and a second substrate 120. The first substrate 110 and the second substrate 120 may be light-transmissive substrates. In the third direction D3 (Z-axis direction), the second substrate 120 is disposed on the first substrate 110, and the first light-emitting element 121A, the second light-emitting element 123A and the third light-emitting element 125A are disposed on the first substrate 110. The material of the first substrate 110 or the second substrate 120 may be a plate-like object that has supportive properties and may reduce the bending, wrinkling and/or deformation of the first substrate 110 or the second substrate 120. For example, the material of the first substrate 110 or the second substrate 120 may include glass, quartz or other suitable materials, or a combination of the above materials, but the disclosure is not limited thereto.

In certain embodiments, the first substrate 110 may be formed through curing of a liquid and/or gel-like initial material. The formation method of the first substrate 110 may include applying the liquid and/or gel-like initial material onto the first substrate 110, and subsequently utilizing a curing process to cure the liquid and/or gel-like initial material to form a flexible first substrate 110. The applicable curing processes may include thermal curing, photo-curing, or a combination thereof, but the disclosure is not limited thereto. The material of the first substrate 110 may include polyimide (PI), polyethylene terephthalate (PET), or a single layer structure of one of other applicable materials, or a stack or mixture of at least two of the above materials, but not limited thereto. In other words, the first substrate 110 may be a single-layer substrate or a multi-layer substrate formed by stacking multiple layers.

In some embodiments, the first substrate 110 may be a circuit board, an active element substrate, or other substrates that may be used to provide driving signals and/or power to the first sub-pixel 121, the second sub-pixel 123, and the third sub-pixel 125. When the first substrate 110 is a circuit board, the first substrate 110 may include multiple conductive circuit layers and multiple insulating layers for separating the multiple conductive circuit layers, but the disclosure is not limited thereto.

Specifically, the first substrate 110 includes an electrode 121B for electrically connecting the first light-emitting element 121A, an electrode 123B for electrically connecting the second light-emitting element 123A, and an electrode 125B for electrically connecting the third light-emitting element 125A. The electrode 121B, the electrode 123B, and the electrode 125B may be pixel electrodes of the first sub-pixel 121, the second sub-pixel 123, and the third sub-pixel 125, respectively, but the disclosure is not limited thereto.

The light-emitting element may include, for example, an organic light-emitting diode (OLED), a mini light-emitting diode (mini LED), a micro light-emitting diode (micro LED), or a quantum dot light-emitting diode (quantum dot, QD, such as QLED, QDLED), fluorescence, phosphor, or other suitable materials, and the materials may be any arrangement and combination, but not limited thereto.

The first color conversion structure 121C may be a quantum dot color conversion structure or a polymer color conversion structure. The first color conversion structure 121C may absorb short-wavelength light and convert it into long-wavelength light. For example, the first color conversion structure 121C may absorb short-wavelength ultraviolet light (wavelength range of about 1 nm to 380 nm), violet light (wavelength range of about 380 nm to 450 nm), blue light (wavelength range of about 450 nm to 495 nm), and convert them into long-wavelength red light (wavelength range of about 620 nm to 750 nm), yellow light (wavelength range of about 570 nm to 590 nm), or green light (wavelength range of about 495 nm to 570 nm), etc. The first color conversion structure 121C is disposed on the first light-emitting element 121A and is configured to absorb and convert the light emitted by the first light-emitting element 121A. As a result, the light emitted by the first light-emitting element 121A is short-wavelength light that may be absorbed by the first color conversion structure 121C, such as blue light, ultraviolet light, or deep ultraviolet light.

The wavelength of light emitted by the first color conversion structure 121C after absorbing the short-wavelength light may be determined according to parameters such as the material and microstructure of the first color conversion structure 121C. Therefore, based on the selection of the material, the light emitted by the first color conversion structure 121C may have a specific color that is different from the color of the light absorbed. In this embodiment, the first light-emitting element 121A emits light of a first color C1. The first color conversion structure 121C is disposed on the first light-emitting element 121A, and is adapted to convert the light of the first color C1 emitted by the first light-emitting element 121A into light of a third color C3.

The second sub-pixel 123 includes a second light-emitting element 123A. The second light-emitting element 123A emits light of a second color C2. The light of the second color C2 is different from the light of the first color C1. The wavelength of light emitted by the second light-emitting element 123A is greater than the wavelength of light emitted by the first light-emitting element 121A. The first color C1 is, for example, blue, the second color C2 may be light with a wavelength longer than blue, such as green, yellow or red, and the third color C3 may be light with a wavelength longer than green, such as yellow or red.

The third sub-pixel 125 may be adjacent to the first sub-pixel 121 or the third sub-pixel 125 may be adjacent to the second sub-pixel 123. In other words, the third sub-pixel 125 is adjacent to at least one of the first sub-pixel 121 or the second sub-pixel 123. The third sub-pixel 125 includes a third light-emitting element 125A. The third light-emitting element 125A emits light of the first color C1. As a result, the first sub-pixel 121, the second sub-pixel 123, and the third sub-pixel 125 are configured to present the third color C3, the second color C2, and the first color C1, respectively, thereby realizing a multi-colored picture on the display device. In some embodiments, the first color C1, the second color C2, and the third color C3 are blue, green, and red, respectively, but not limited thereto. For example, the first color C1, the second color C2, and the third color C3 may respectively be three different colors of light in the visible spectrum.

In some embodiments, the first sub-pixel 121, the second sub-pixel 123, and the third sub-pixel 125 may be arranged in a first color sequence or a second color sequence along a first direction D1. The term “color sequence” refers to the order of the emitted colors of the sequentially arranged sub-pixels. For example, the first color sequence is red-green-blue, and the second color sequence is blue-green-red.

FIG. 1C is a diagram showing the relationship between the viewing angle and the brightness of the second sub-pixel according to an embodiment of the disclosure. FIG. 1D is a diagram showing the relationship between the viewing angle and the brightness of the third sub-pixel according to an embodiment of the disclosure. The scattering particle layer SOC is located between the second light-emitting element 123A and the third light-emitting element 125A, on at least one side of the second light-emitting element 123A, and on at least one side of the third light-emitting element 125A, which may effectively suppress the cross talk phenomenon of color conversion light, thereby reducing the occurrence of color deviation in the light-emitting device at large viewing angles.

For example, when the light-emitting device is viewed at a large angle from a position adjacent to the first sub-pixel 121, since the first sub-pixel 121 is closer to the viewer and the third-color sub-pixel 125 is farther away from the viewer, and since the scattering particle layer SOC is located between the second light-emitting element 123A and the third light-emitting element 125A, the cross talk phenomenon of color conversion light may be effectively suppressed, thereby reducing the occurrence of color deviation in the light-emitting device at large viewing angles. In addition, when the light-emitting device is viewed at a large angle from a position adjacent to the third sub-pixel 125, since the third sub-pixel 125 is closer to the viewer and the first color sub-pixel 121 is farther away from the viewer, and since the scattering particle layer SOC is located between the second light-emitting element 123A and the third light-emitting element 125A, the cross talk phenomenon of color conversion light may be effectively suppressed, thereby reducing the occurrence of color deviation in the light-emitting device at large viewing angles.

FIG. 1C and FIG. 1D respectively depict the comparison between when the second sub-pixel 123 and the third sub-pixel 125 incorporate the scattering particle layer SOC and the optically clear adhesive layer OC, versus the conventional approach of incorporating only the optically clear adhesive layer OC. It may be seen from FIG. 1C and FIG. 1D that when the scattering particle layer SOC is located between the second light-emitting element 123A and the third light-emitting element 125A, the brightness of the second sub-pixel 123 and the third sub-pixel 125 at each viewing angle is uniform and symmetrical. Therefore, the overall emitted color of the light-emitting device as viewed by a viewer is less likely to be biased toward the color of the first color sub-pixel 121, the color of the second color sub-pixel 123, or the color of the third color sub-pixel 125. In other words, the color deviation phenomenon that may occur in the light-emitting device 100 may be mitigated.

n detail, the display device is filled with an optically clear adhesive layer OC to effectively inhibit water and oxygen penetration and thereby improve the arithmetic average roughness (RA). The addition of high refractive index scattering particles SP to the scattering particle layer SOC may also increase the light emission viewing angle. The optically clear adhesive layer OC overlays directly above the second light-emitting element 123A or the third light-emitting element 125A, and the scattering particle layer SOC surrounds the second light-emitting element 123A or the third light-emitting element 125A. This architecture may be achieved through a photoresist packaging layer. Referring to FIG. 1C and FIG. 1D, which show that the viewing angle distribution of the second sub-pixel 123 or the third sub-pixel 125 may be bilaterally symmetrical, with a slight decrease at 30 degrees due to the interface between the clear and high-refractive packaging layer. The brightness at front viewing angle is slightly higher than that of a display device with only the optically clear adhesive layer OC packaging. Therefore, the display device of the disclosure utilizes the composite packaging (optically clear adhesive layer OC+scattering particle layer SOC) to not only maintain the original emission brightness of the original display device, but also effectively adjust and solve the viewing angle deviation problem, thereby improving the display quality of the display device.

Referring to FIG. 1B, in the present embodiment, the first region R1 may further include a first filter layer CF1, and the first color conversion layer 121C is disposed between the first filter layer CF1 and the first light-emitting element 121A. The second region R2 further includes a second filter layer CF2 disposed on the second light-emitting element 123A and the third light-emitting element 125A.

The first region R1 further includes an optically clear adhesive layer OC. The filter layer CF1 is disposed on the first color conversion layer 121C. The optically clear adhesive layer OC is disposed between the filter layer CF1 and the first color conversion layer 121C. The second region R2 further includes an optically clear adhesive layer OC. The filter layer CF2 is disposed on the second light-emitting element 123A. The optically clear adhesive layer OC is disposed between the filter layer CF2 and the second light-emitting element 123A.

The optically clear adhesive layer OC may selectively provide functions required by the display device, such as a moisture barrier function, an optical adjustment function, thereby enhancing the optical quality of the display device. The thickness of the optically clear adhesive layer OC in the first region R1 along the third direction D3 (Z-axis direction) is less than the thickness of the optically clear adhesive layer OC in the second region R2 along the third direction D3 (Z-axis direction).

The filter layer CF1 of the first region R1 and the filter layer CF2 of the second region R2 are both disposed on the surface of the second substrate 120 facing the first substrate 110. The filter layer may be configured to improve color purity. For example, the filter layer may include an absorptive color photoresist, and the filter layer CF1 may allow at least a portion of the light of the third color C3 to pass through and filter the light of the remaining colors. If there is no filter layer CF1 on the first color conversion structure 121C, the light of the third color C3 is the light that passes through the first color conversion structure 121C. If there is a filter layer/filter pattern on the first color conversion structure 121C, the light of the third color C3 is the light that passes through the filter layer CF1.

The blocking layer WB is disposed on a surface of the first substrate 110 facing the second substrate 120. The material of the blocking layer WB may include a light absorbing material, such as black photoresist, white photoresist, or photoresist of other colors, but not limited thereto. In some embodiments, although not shown, in addition to the light absorbing material, the material of the blocking layer WB may further include light scattering particles, but not limited thereto. In other embodiments, the material of the blocking layer WB may include a light-transmissive material (such as a clear photoresist) and a reflective layer or a light-absorbing layer disposed on the light-transmissive material.

Multiple light blocking elements BM may be disposed on a surface of the first substrate 110 facing the second substrate 120 and located between the blocking layer WB and the second substrate 120. The material of the light blocking elements BM may include black resin, gray resin, white resin or metal, but not limited thereto.

Referring to FIG. 1A, from a top view, a first color conversion structure 121C, a blocking layer WB, and a scattering particle layer SOC may be sequentially disposed along the first direction D1 (X-axis direction) between the first light-emitting element 121A and the second light-emitting element 123A.

From a top view, the first light-emitting element 121A, the second light-emitting element 123A and the third light-emitting element 125A are sequentially arranged along the first direction D1. The first light-emitting element 121A defines a first side 121S1 and a second side 121S2 along the first direction D1, the second light-emitting element 123A defines a first side 123S1 and a second side 123S2 along the first direction D1, and the third light-emitting element 125A defines a first side 125S1 and a second side 125S2 along the first direction D1, respectively. The distance between the second side 121S2 of the first light-emitting element 121A and the first side 123S1 of the second light-emitting element 123A is less than the distance between the first side 121S1 of the first light-emitting element 121A and the first side 123S1 of the second light-emitting element 123A. The distance between the second side 123S2 of the second light-emitting element 123A and the first side 125S1 of the third light-emitting element 125A is less than the distance between the first side 123S1 of the second light-emitting element 123A and the first side 125S1 of the third light-emitting element 125A.

From a top view, the scattering particle layer SOC may be disposed between the second side 123S2 of the second light-emitting element and the first side 125S1 of the third light-emitting element 125A. In some embodiments, the scattering particle layer SOC is positioned without a spacing between the second side 123S2 of the second light-emitting element and the first side 125S1 of the third light-emitting element.

It should be noted that the following embodiments use the reference numerals and a part of the contents of the above embodiments, and similar reference numerals are used to denote the same or similar elements, and the description of the same technical contents is omitted. For the description of the omitted part, reference may be made to the above embodiments, and details are not described in the following embodiments.

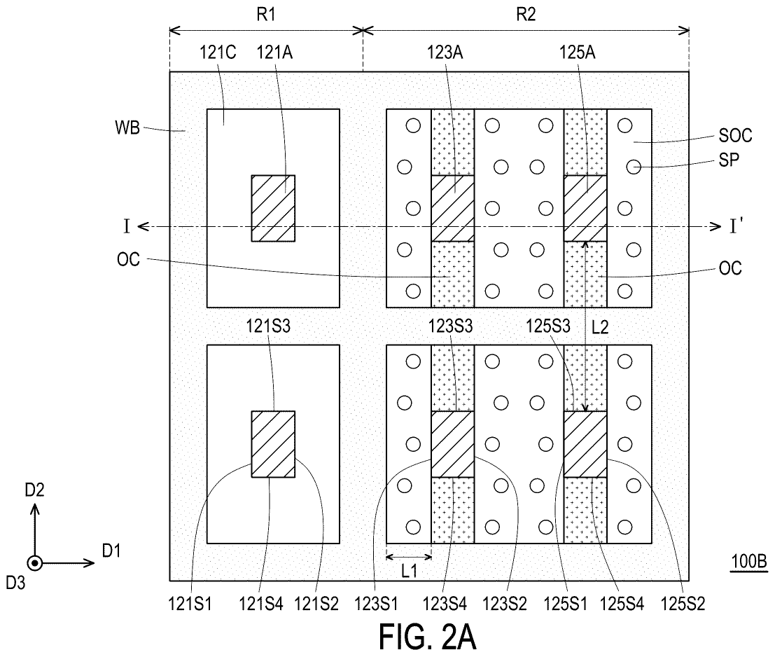

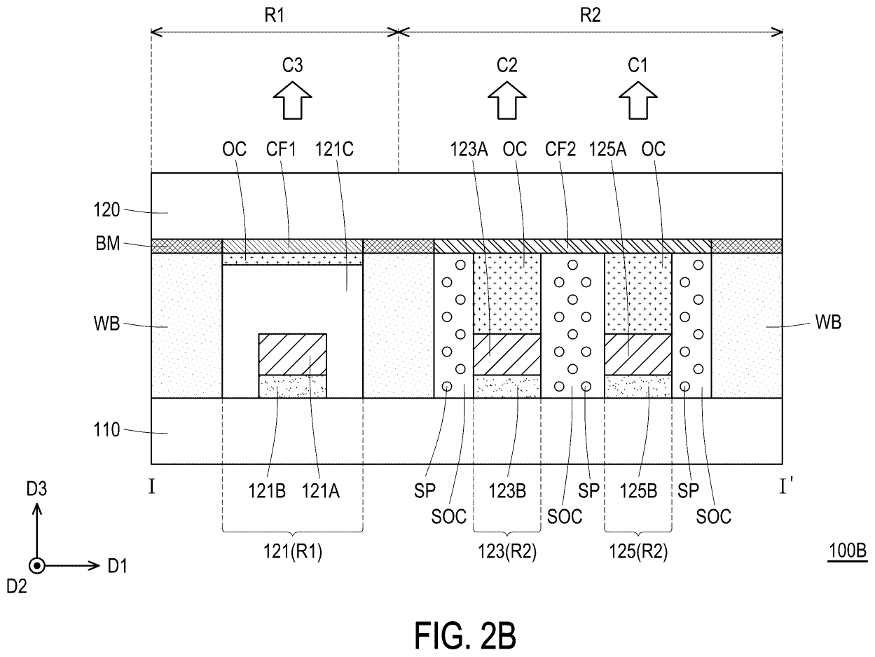

FIG. 2A is a top schematic view of a pixel unit according to an embodiment of the disclosure. FIG. 2B is a cross-sectional schematic diagram of FIG. 2A along the section line I-I′. Please refer to FIG. 2A and FIG. 2B simultaneously. The pixel unit 100B is similar to the pixel unit 100A, and the main difference is that, from a top view, the blocking layer WB may be disposed between the second side 121S2 of the first light-emitting element 121A and the first side 123S1 of the second light-emitting element 123A, and a spacing L1 may exist between the blocking layer WB and the first side 123S1 of the second light-emitting element 123A along the first direction D1. The range of the spacing L1 is, for example, less than or equal to 12 microns and greater than or equal to 1 micron.

From a top view, the second light-emitting elements 123A of the second region R2 may be sequentially disposed along the second direction D2 (Y-axis direction). Each second light-emitting element 123A has a third side 123S3 and a fourth side 123S4 along the second direction D2. The distance between the third side 123S3 of each second light-emitting element 123A and the fourth side 123S4 of an adjacent second light-emitting element 123A along the second direction D2 is less than the distance between the third side 123S3 of each second light-emitting element 123A and the third side 123S3 of an adjacent second light-emitting element 123A along the second direction D2. The optically clear adhesive layer OC and the blocking layer WB are provided between the third side 123S3 of the second light-emitting element 123A and the fourth side 123S4 of the second light-emitting element 123A, and the blocking layer WB is disposed between the optically clear adhesive layers OC.

In this embodiment, the second light-emitting element 123A and the third light-emitting element 125A may have varying distances from the blocking layer WB depending on the shape of the light-emitting elements. The commonly used light-emitting element is a long strip. Due to the pixel configuration of the display device, the distance between the light-emitting element and the upper and lower adjacent blocking layers WB is longer, while the distance to the left and right adjacent blocking layers WB is shorter. The viewing angle narrowing ratio is inversely proportional to the distance from the blocking wall, resulting in the upper and lower viewing angles being greater than the left and right viewing angles. From a top view, the second light-emitting element 123A and the third light-emitting element 125A may be packaged with an optically clear adhesive layer OC on the top and bottom (second direction D2), and may be packaged with a scattering particle layer SOC on the left and right (first direction D1). The upper and lower viewing angles may maintain better light emission efficiency, and the left and right viewing angles may be improved by composite packaging (optically clear adhesive layer OC +scattering particle layer SOC) to improve the viewing angle while maintaining the light emission efficiency, so that the display device may have better display quality.

A spacing L2 exists between the third side 123S3 of the second light-emitting element 123A and the fourth side 123S4 of the second light-emitting element 123A of the second light-emitting elements 123A sequentially arranged along the second direction D2. The spacing L1 is less than the spacing L2, and the range of the spacing L2 is less than or equal to 50 microns and greater than or equal to 15 microns.

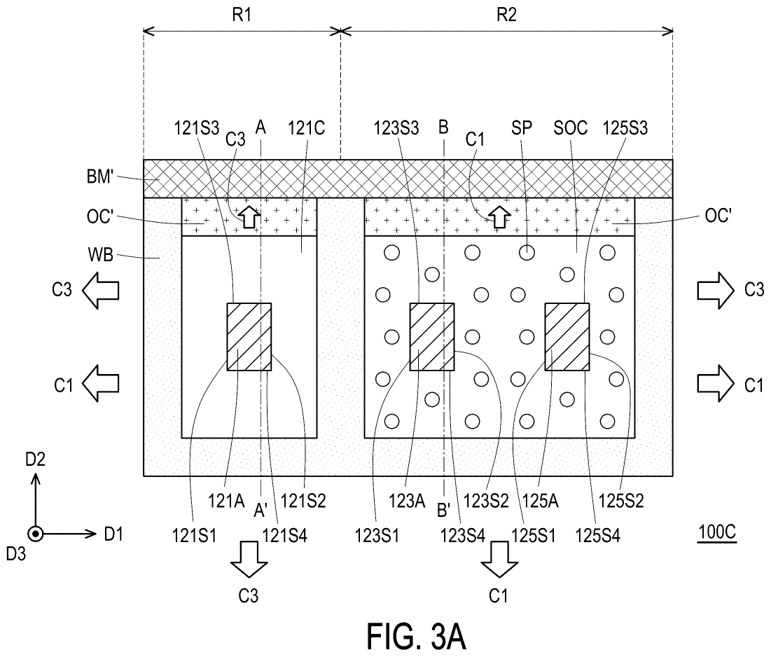

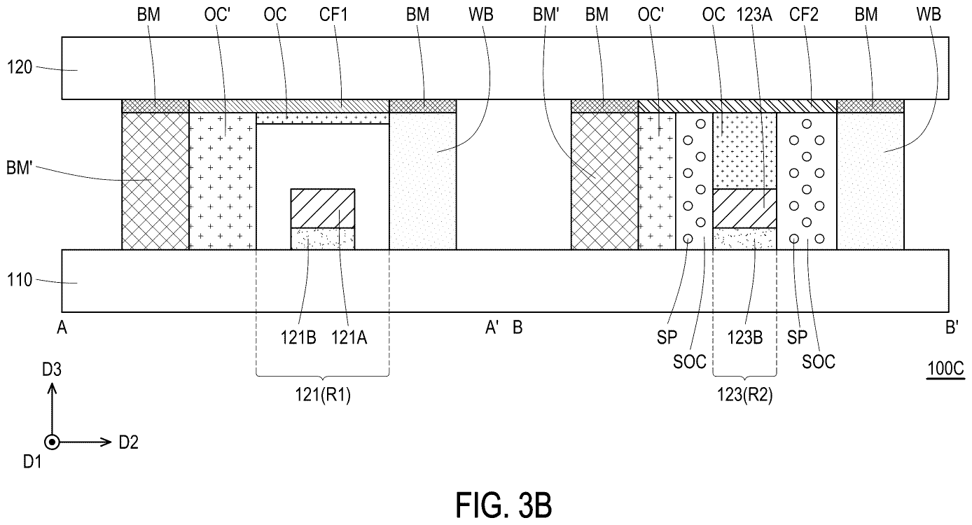

FIG. 3A is a top schematic view of a pixel unit according to an embodiment of the disclosure. FIG. 3B is a cross-sectional schematic diagram of FIG. 3A along the section line A-A′ and the section line B-B′. The pixel unit 100C is similar to the pixel unit 100A, and the main difference is that, from a top view, the third side 121S3 of the first light-emitting element 121A, the third side 123S3 of the second light-emitting element 123A, and the third side 125S3 of the third light-emitting element 125A may be sequentially provided with an optically clear adhesive layer OC′ and a light blocking element BM′ along the second direction D2. The optically clear adhesive layer OC′ is located between the light blocking element BM′ and the first light-emitting element 121A or the second light-emitting element 123A or the third light-emitting element 125A. There is no blocking layer WB between the light blocking element BM′ and the optically clear adhesive layer OC′. The light blocking element BM′ is adjacent to the third side 121S3 of the first light-emitting element 121A, the third side 123S3 of the second light-emitting element 123A and the third side 125S3 of the third light-emitting element 125A. That is, the normal direction (second direction D2) of the light blocking element BM′ is parallel to the normal direction (second direction D2) of the third side 121S3 of the first light-emitting element, the normal direction (second direction D2) of the third side 123S3 of the second light-emitting element, and the normal direction (second direction D2) of the third side 125S3 of the third light-emitting element. The light of the first color C1 and the light of the third color C3 may be emitted from the adjacent first side 121S1 of the first light-emitting element 121A, the fourth side 121S 4 of the first light-emitting element 121A, the fourth side 123S4 of the second light-emitting element 123A, the fourth side 125S4 of the third light-emitting element 125A, and the second side 125S2 of the third light-emitting element 125A. However, the light of the first color C1 and the light of the third color C3 on the third side 121S3 of the first light-emitting element 121A, the third side 123S3 of the second light-emitting element 123A, and the third side 125S3 of the third light-emitting element 125A are blocked by the light blocking element BM′. That is, the display device has only three light-emitting surfaces.

The optically clear adhesive layer OC and the optically clear adhesive layer OC′ may have different refractive indices. In some embodiments, the refractive index of the optically clear adhesive layer OC is greater than the refractive index of the optically clear adhesive layer OC′, but the disclosure is not limited thereto.

When the vehicle display device or the central information display (CID) is located near the windshield, the image projection may interfere with the line of sight. Therefore, the composite packaging material stacked layer of the disclosure may be used on a specific side of the display device to reduce the light emitted in a specific direction and recycle it to other directions, thereby reducing the optical loss of the display device. In addition, the light blocking element BM′ may be used in conjunction to effectively control the brightness of the light-emitting surfaces of the display, reduce the impact of the projected image, and improve the display quality.

In some embodiments, the light blocking element BM′ may be disposed adjacent to the first side 121S1 of the first light-emitting element, that is, the normal direction (first direction D1) of the light blocking element BM′ is parallel to the normal direction (first direction D1) of the first side 121S1 of the first light-emitting element 121A. The optically clear adhesive layer OC′ is located between the light blocking element BM′ and the first light-emitting element 121A, and there is no blocking layer WB between the light blocking element BM′ and the optically clear adhesive layer OC′. The light of the first color C1 and the light of the third color C3 may be emitted from the adjacent third side 121S3 of the first light-emitting element 121A, the third side 123S3 of the second light-emitting element 123A, the third side 125S3 of the third light-emitting element 125A and the second side 125S2 of the third light-emitting element 125A, the fourth side 125S4 of the third light-emitting element 125A, the fourth side 123S4 of the second light-emitting element 123A and the fourth side 121S4 of the first light-emitting element 121A. However, the light of the first color C1 and the light of the third color C3 on the first side 121S1 of the first light-emitting element 121A are blocked by the light blocking element BM′. That is, the display device has only three light-emitting surfaces.

In some embodiments, the light blocking element BM′ may be disposed adjacent to the second side 125S2 of the third light-emitting element 125A, that is, the normal direction (first direction D1) of the light blocking element BM′ is parallel to the normal direction (first direction D1) of the second side 125S2 of the third light-emitting element 125A. The optically clear adhesive layer OC′ is located between the light blocking element BM′ and the third light-emitting element 125A, and there is no blocking layer WB between the light blocking element BM′ and the optically clear adhesive layer OC′. The light of the first color C1 and the light of the third color C3 may be emitted from the adjacent first side 121S1 of the first light-emitting element 121A, the third side 121S3 of the first light-emitting element 121A, the third side 123S3 of the second light-emitting element 123A, the third side 125S3 of the third light-emitting element 125A, the fourth side 125S4 of the third light-emitting element 125A, the fourth side 123S4 of the second light-emitting element 123A, and the fourth side 121S4 of the first light-emitting element 121A. However, the light of the first color C1 and the light of the third color C3 at the second side 125S2 of the third light-emitting element 125A are blocked by the light blocking element BM′. That is, the display device has only three light-emitting surfaces.

In some embodiments, the light blocking element BM′ may be disposed adjacent to the fourth side 121S4 of the first light-emitting element 121A, the fourth side 123S4 of the second light-emitting element 123A, and the fourth side 125S4 of the third light-emitting element 125A. That is, the normal direction (the second direction D2) of the light blocking element BM′ is parallel to the normal direction (second direction D2) of the fourth side 121S4 of the first light-emitting element 121A, the normal direction (second direction D2) of the fourth side 123S4 of the second light-emitting element 123A, and the normal direction (second direction D2) of the fourth side 125S4 of the third light-emitting element 125A. The optically clear adhesive layer OC′ is located between the light blocking element BM′ and the first light-emitting element 121A or the second light-emitting element 123A or the third light-emitting element 125A. There is no blocking layer WB between the light blocking element BM′ and the optically clear adhesive layer OC′. The light of the first color C1 and the light of the third color C3 may be emitted from the first side 121S1 adjacent to the first light-emitting element 121A, the third side 121S3 of the first light-emitting element 121A, the third side 123S3 of the second light-emitting element 123A, the third side 125S3 of the third light-emitting element 125A and the second side 125S2 of the third light-emitting element 125A. However, the light of the first color C1 and the light of the third color C3 on the fourth side 121S4 of the first light-emitting element 121A, the fourth side 123S4 of the second light-emitting element 123A and the fourth side 125S4 of the third light-emitting element 125A are blocked by the light blocking element BM′. That is, the display device has only three light-emitting surfaces.

To sum up, the first color conversion structure of the disclosure covers the first light-emitting element, the blocking layer surrounds the first light-emitting element, and the scattering particle layer is located between the second light-emitting element and the third light-emitting element, at least one side of the second light-emitting element, and at least one side of the third light-emitting element. In this way, the display device may effectively suppress the cross talk phenomenon of color conversion light, and the display device may have better picture quality.

What is claimed is:

1. A display device, comprising:
a pixel unit, comprising:
a first region, comprising:
a first sub-pixel, comprising:
a first light-emitting element, emitting light of a first color; and
a first color conversion structure, disposed on the first light-emitting element, covering the first light-emitting element and adapted to convert the light of the first color emitted by the first light-emitting element into light of a second color; and
a blocking layer, surrounding the first light-emitting element; and
a second region, comprising:
a second sub-pixel, comprising:
a second light-emitting element, emitting light of a third color;
a third sub-pixel, comprising:
a third light-emitting element, emitting light of the first color; and
a scattering particle layer, wherein the scattering particle layer is located between the second light-emitting element and the third light-emitting element, on at least one side of the second light-emitting element, and on at least one side of the third light-emitting element.

2. The display device according to claim 1, wherein the first region further comprises a first filter layer, and the first color conversion layer is disposed between the first filter layer and the first light-emitting element.

3. The display device according to claim 1, wherein the second region further comprises a second filter layer disposed on the second light-emitting element and the third light-emitting element.

4. The display device according to claim 1, wherein the first region further comprises a first filter layer and a first optically clear adhesive layer, the first filter layer is disposed on the first color conversion layer, the first optically clear adhesive layer is disposed between the first filter layer and the first color conversion layer.

5. The display device according to claim 4, wherein the second region further comprises a second filter layer and a second optically clear adhesive layer, the second filter layer is disposed on the second light-emitting element, the second optically clear adhesive layer is disposed between the second filter layer and the second light-emitting element.

6. The display device according to claim 5, wherein a thickness of the first optically clear adhesive layer along a third direction is less than a thickness of the second optically clear adhesive layer along the third direction.

7. The display device according to claim 1, wherein, from a top view, the first color conversion structure, the blocking layer and the scattering particle layer are sequentially disposed along a first direction between the first light-emitting element and the second light-emitting element.

8. The display device according to claim 1, wherein, from a top view, the blocking layer is disposed between a second side of the first light-emitting element and a first side of the second light-emitting element, and the scattering particle layer is disposed between a second side of the second light-emitting element and a first side of the third light-emitting element.

9. The display device according to claim 8, wherein, from the top view, a first spacing exists between the blocking layer and the first side of the second light-emitting element along a first direction, a second spacing exists between a third side of the second light-emitting element and a fourth side of the second light-emitting element of the second light-emitting elements sequentially disposed along a second direction, and the first spacing is less than the second spacing.

10. The display device according to claim 9, wherein a range of the first spacing is less than or equal to 12 microns and greater than or equal to 1 micron.

11. The display device according to claim 9, wherein a range of the second spacing is less than or equal to 50 microns and greater than or equal to 15 microns.

12. The display device according to claim 5, wherein, from a top view, the blocking layer is provided between a third side of the second light-emitting element and a fourth side of the second light-emitting element of the second light-emitting elements of the second region sequentially disposed along a second direction, the blocking layer is disposed between the second optically clear adhesive layers.

13. The display device according to claim 4, wherein, from a top view, a third side of the second light-emitting element is sequentially provided with a third optically clear adhesive layer and a light blocking element along a second direction, the third optically clear adhesive layer is located between the light blocking element and the second light-emitting element.

14. The display device according to claim 13, wherein the first optically clear adhesive layer and the third optically clear adhesive layer have different refractive indices.

15. The display device according to claim 14, wherein a refractive index of the first optically clear adhesive layer is greater than a refractive index of the third optically clear adhesive layer.

16. A display device, comprising:
a pixel unit, comprising:
a first region, comprising:
a first sub-pixel, comprising:
a first light-emitting element, emitting light of a first color; and
a first color conversion structure, disposed on the first light-emitting element, covering the first light-emitting element and adapted to convert the light of the first color emitted by the first light-emitting element into light of a second color;
a first filter layer, wherein the first color conversion layer is disposed between the first filter layer and the first light-emitting element; and
a blocking layer, surrounding the first light-emitting element; and
a second region, comprising:
a second sub-pixel, comprising:
a second light-emitting element, emitting light of a third color;
a third sub-pixel, comprising:
a third light-emitting element, emitting light of the first color;
a second filter layer, disposed on the second light-emitting element and the third light-emitting element; and
a scattering particle layer, wherein the scattering particle layer is located between the second light-emitting element and the third light-emitting element, on at least one side of the second light-emitting element, and on at least one side of the third light-emitting element.
